(19) United States
(12) Patent Application Publication
(10) Pub. No.: US 2007/0138586 A1
(43) Pub. Date: Jun. 21, 2007

(54) Image sensor module package

(76) Inventors: Chung Hsien Hsin, Hsinchu Hsien (TW); Chen Pin Peng, Hsinchu Hsien (TW); Mon Nan Ho, Hsinchu Hsien (TW)

Correspondence Address: PRO-TECHTOR INTERNATIONAL SERVICES, 20775 NORADA CT., SARATOGA, CA, 95070, US

(21) Appl. No.: 11/305,655

(22) Filed: Dec. 16, 2005

(51) Int. Cl. H01L 31/0203

(52) U.S. Cl. 257/433

(57) ABSTRACT

An image sensor module package includes a substrate having an upper surface, which is formed with a chip region and first electrodes located on the periphery of the chip region, and a lower surface. A chip is mounted on the chip region of the upper surface of the substrate. A frame layer is arranged on the upper surface of the substrate to surround the chip. Four posts are arranged on the upper surface of the substrate and are located on the angle the frame layer. A plurality of wires are electrically connected the bonding pads of the chip to the first electrodes of the substrate. A transparent layer is mounted on the four posts to cover the chip. A lens holder is mounted on the frame layer, and is formed with an internal thread. And a lens barrel is formed with an external thread screwed on the internal thread of the lens holder.

### BACKGROUND OF THE INVENTION

1. Field of the Invention

The invention relates an image sensor module package, and particular to a structure for packaging image sensor module, the size of the package may be decreased.

2. Description of the Related Art

Referring to FIG. 1, it is an image sensor module structure includes a substrate 10, frame layer 18, a chip 26, a plurality of wires 28, transparent layer 34, a lens holder 35 and a lens barrel 46.

The substrate 10 has an first surface 12 on which plurality of first electrodes 15 are formed, and a second surface 14 on which plurality of second electrodes16 are formed, the first electrodes 15 are corresponding to electrically connect to the second electrodes 16.

The frame layer 18 has a upper surface 20 and a lower surface 22, the lower surface 22 of the frame layer 18 is adhered on the first surface 22 of the substrate 10 to form a cavity 24.

The chip 26 is arranged on the first surface 12 of the substrate 10, and is located within the cavity 24, and is formed with bonding pads 27.

The wire 28 has a first end 30 and a second end 32, the first end 30 is electrically connected the bonding pad 27 of the chip 26, the second end 30 is electrically connected the first electrodes 15 of the substrate 10.

The transparent layer 34 is adhered on the upper surface 20 of the frame layer 18.

The lens holder 35 has an upper end surface 36, a lower end surface 40, and a penetrated region 42, which is formed with internal thread 44.

The lens barrel 46 is formed with external thread 39 screwed on the internal thread 44 of the lens holder 35, an opening 47, an aspheric lens 481, and an infrared filter 49.

### SUMMARY OF THE INVENTION

An objective of the invention is to provide an image sensor module package, and capable of decreasing the size of the module.

To achieve the above-mentioned object, the invention includes a substrate having an upper surface, which is formed with a chip region and first electrodes located on the periphery of the chip region, and a lower surface. A chip is mounted on the chip region of the upper surface of the substrate. A frame layer is arranged on the upper surface of the substrate to surround the chip. Four posts are arranged on the upper surface of the substrate and are located on the angle the frame layer. A plurality of wires are electrically connected the bonding pads of the chip to the first electrodes of the substrate. A transparent layer is mounted on the four posts to cover the chip. A lens holder is mounted on the frame layer, and is formed with an internal thread. And a lens barrel is formed with an external thread screwed on the internal thread of the lens holder.

### BRIEF DESCRIPTION OF THE DRAWINGS

FIG. 1 is a schematic illustration showing a conventional image sensor module package.

FIG. 2 is a cross-sectional schematic illustration showing an image sensor module package of the present invention.

FIG. 3 is a top-view schematic illustration showing an image sensor module package of the present invention.

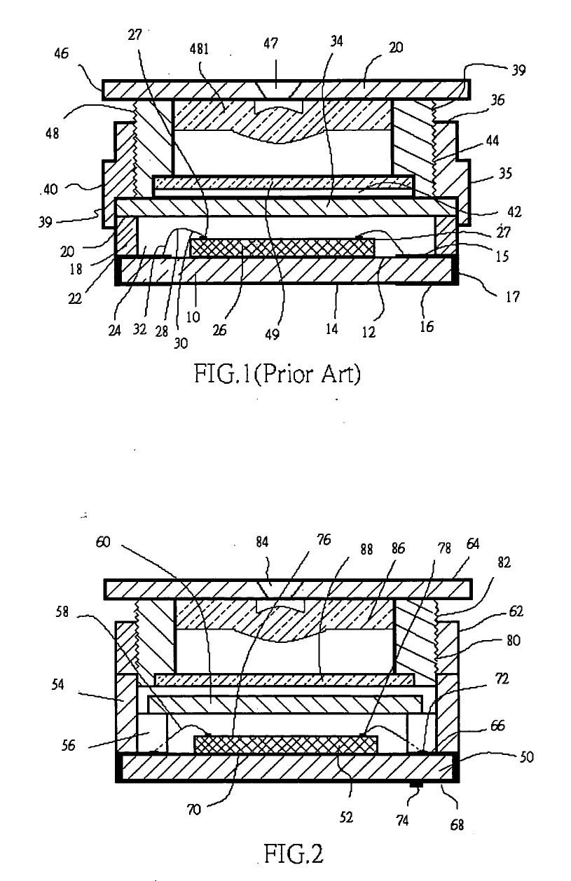

### DETAILED DESCRIPTION OF THE INVENTION

Please refer to FIG. 2, an image sensor module package includes a substrate 50, a chip 52, a frame layer 54, four posts 56, wires 58, a transparent layer 60, a lens holder 62, and a lens barrel 64.

The substrate 50 has an upper surface 66, which is formed with a chip region 70 and first electrodes 72 are located on the periphery of the chip region 70, and a lower surface 68, which is formed with second electrodes 74 corresponding to electrically connect to the first electrodes 72.

The chip 52 is mounted on the chip region 70 of the upper surface 66 of the substrate 50, the chip has a sensor region 76 and a plurality of bonding pads 78 located at the side of the sensor region 70 of the chip 52.

The frame layer 54 is arranged on the upper surface 66 of the substrate 50 to surround the chip region 70 and the first electrodes 72.

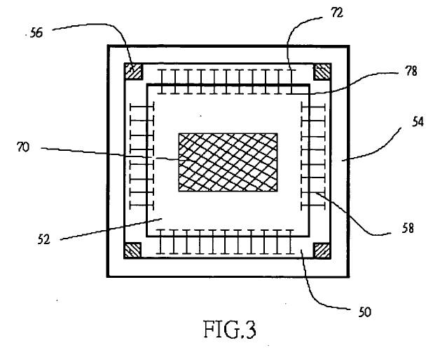

Please refer to FIG.3, the four posts 56 are arranged on the upper surface 66 of the substrate 50 and are located on the angle the frame layer 54.

The plurality of wires 58 are electrically connected the bonding pads 78 of the chip 52 to the first electrodes 72 of the substrate 50.

The transparent layer 60 is mounted on the four posts 56 to cover the chip 52.

The lens holder 62 is mounted on the frame layer 54, and formed with an internal thread 80. And

The lens barrel 64 is formed with an external thread 82 screwed on the internal thread 80 of the lens holder 62, and an opening 84, an aspheric lens 86, and an infrared filter 88.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor module package, the package comprising;
a substrate having an upper surface, which is formed with a chip region and first electrodes located on the periphery of the chip region, and a lower surface, which is formed with second electrodes corresponding to electrically connect to the first electrodes;
a chip mounted on the chip region of the upper surface of the substrate, the chip having a sensor region and a plurality of bonding pads located at the side of the sensor region of the chip;
a frame layer arranged on the upper surface of the substrate to surround the chip region and the first electrodes;
four posts arranged on the upper surface of the substrate and located on the angle the frame layer;
a plurality of wires electrically connected the bonding pads of the chip to the first electrodes of the substrate;
a transparent layer mounted on the four posts to cover the chip;
a lens holder mounted on the frame layer, and formed with an internal thread; and
a lens barrel formed with an external thread screwed on the internal thread of the lens holder.

2. The image sensor module package according to claim 1, wherein the height of the four posts are lower than the frame layer.

3. The image sensor module package according to claim 1, wherein the lens barrel is formed with an opening, an aspheric lens, and an infrared filter.
